(19) United States
(12) Patent Application Publication
(10) Pub. No.: US 2023/0011666 A1
(43) Pub. Date: Jan. 12, 2023

(54) SEMICONDUCTOR PACKAGE STRUCTURE

(71) Applicant: MediaTek Singapore Pte. Ltd., Singapore (SG)

(72) Inventors: Chang LIANG, Singapore (SG); Zhigang DUAN, Singapore (SG); Tai-Yu CHEN, Hsinchu City (TW); Fa-Chuan CHEN, Hsinchu City (TW)

(21) Appl. No.: 17/841,810

(22) Filed: Jun. 16, 2022

Related U.S. Application Data
(60) Provisional application No. 63/219,854, filed on Jul. 9, 2021.

(51) Int. Cl. H01L 49/02; H01L 25/16; H01L 23/00

(52) U.S. Cl. CPC H01L 28/90; H01L 25/162; H01L 24/24; H01L 2224/24265; H01L 2924/19041

(57) ABSTRACT

A semiconductor package structure includes a substrate, a first redistribution layer, a semiconductor die, a silicon capacitor, and a first bump structure. The first redistribution layer is disposed over the substrate. The semiconductor die is disposed over the first redistribution layer. The silicon capacitor is disposed below the first redistribution layer and is electrically coupled to the semiconductor die, wherein the silicon capacitor includes a semiconductor substrate and a plurality of capacitor cells embedded in the semiconductor substrate. The first bump structure is disposed between the silicon capacitor and the substrate.

### CROSS REFERENCE TO RELATED APPLICATIONS

This application claims the benefit of U.S. Provisional Application No. 63/219,854 filed on Jul. 9, 2021, the entirety of which is incorporated by reference herein.

### BACKGROUND OF THE INVENTION

### Field of the Invention

The present invention is related to semiconductor technology, and in particular to a semiconductor package structure including a capacitor.

### Description of the Related Art

A semiconductor package structure can not only provide a semiconductor die with protection from environmental contaminants, but it can also provide an electrical connection between the semiconductor die packaged therein and a substrate, such as a printed circuit board (PCB). Heat is generated during operation of the semiconductor die. If the heat is not adequately removed, the increased temperature may result in damage to the semiconductor components. However, with the increase in demand for smaller devices that can perform more functions, the thermal management of semiconductor packages has become increasingly difficult.

In addition, decoupling capacitors are generally used as temporary charge reservoirs to prevent momentary fluctuations in supply voltage. These decoupling capacitors are more and more important to reduce power noise during operation of digital circuitry (such as a microprocessor) with numerous transistors that alternate between on and off states. However, the decoupling capacitors may block the thermal conduction, which makes the thermal performance worse. Therefore, there is a need to further improve semiconductor package structures to improve their thermal performance.

### BRIEF SUMMARY OF THE INVENTION

Semiconductor package structures are provided. An exemplary embodiment of a semiconductor package structure includes a substrate, a first redistribution layer, a semiconductor die, a silicon capacitor, and a first bump structure. The first redistribution layer is disposed over the substrate. The semiconductor die is disposed over the first redistribution layer. The silicon capacitor is disposed below the first redistribution layer and is electrically coupled to the semiconductor die. The silicon capacitor includes a semiconductor substrate and a plurality of capacitor cells embedded in the semiconductor substrate. The first bump structure is disposed between the silicon capacitor and the substrate.

Another exemplary embodiment of a semiconductor package structure includes a first redistribution layer, semiconductor die, and a silicon capacitor. The semiconductor die is disposed over the first redistribution layer. The silicon capacitor is disposed below the first redistribution layer and is electrically coupled to the semiconductor die through the first redistribution layer. The silicon capacitor includes a semiconductor substrate, a plurality of capacitor cells, a first bump structure, and a second bump structure. The semiconductor substrate has a first surface and a second surface opposite thereto. The plurality of capacitor cells extend from the first surface of the semiconductor substrate toward the second surface of the semiconductor substrate. The first bump structure is disposed over the first surface of the semiconductor substrate and is electrically coupled to the plurality of capacitor cells. The second bump structure is disposed over the second surface of the semiconductor substrate and is electrically coupled to the first redistribution layer.

Yet another exemplary embodiment of a semiconductor package structure includes a first package structure. The first package structure includes a first redistribution layer, a semiconductor die, a second redistribution layer, a silicon capacitor, and a bump structure. The semiconductor die is disposed over the first redistribution layer. The second redistribution layer is disposed over the semiconductor die. The silicon capacitor is disposed below the first redistribution layer and is electrically coupled to the semiconductor die. The bump structure is disposed below the silicon capacitor.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross-sectional view of an exemplary semiconductor package structure in accordance with some embodiments;

FIG. 2 is a cross-sectional view of a silicon capacitor of an exemplary semiconductor package structure in accordance with some embodiments;

FIG. 3 is a cross-sectional view of a silicon capacitor of an exemplary semiconductor package structure in accordance with some embodiments;

FIG. 4 is a cross-sectional view of a silicon capacitor of an exemplary semiconductor package structure in accordance with some embodiments;

FIG. 5 is a cross-sectional view of a silicon capacitor of an exemplary semiconductor package structure in accordance with some embodiments; and

FIG. 6 is a cross-sectional view of a silicon capacitor of an exemplary semiconductor package structure in accordance with some embodiments.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is determined by reference to the appended claims.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

In the following description, the description of “a first element passing through a second element” or “a first element extending through a second element” may include embodiments in which the first element is in the second element and extends from a side of the second element to an opposite side of the second element, wherein a surface of the first element may be leveled with a surface of the second element, or a surface of the first element may be outside a surface of the second element. In addition, the present disclosure may repeat reference numerals and/or letters in the various embodiments. This repetition is for simplicity and clarity and does not in itself dictate a relationship between the various embodiments discussed.

A semiconductor package structure is described in accordance with some embodiments of the present disclosure. The semiconductor package structure includes a silicon capacitor to transfer the heat from a semiconductor die, so that the thermal performance can be elevated. In addition, the semiconductor package structure includes a bump structure which is electrically coupled to the silicon capacitor, so that the thermal performance can be further improved.

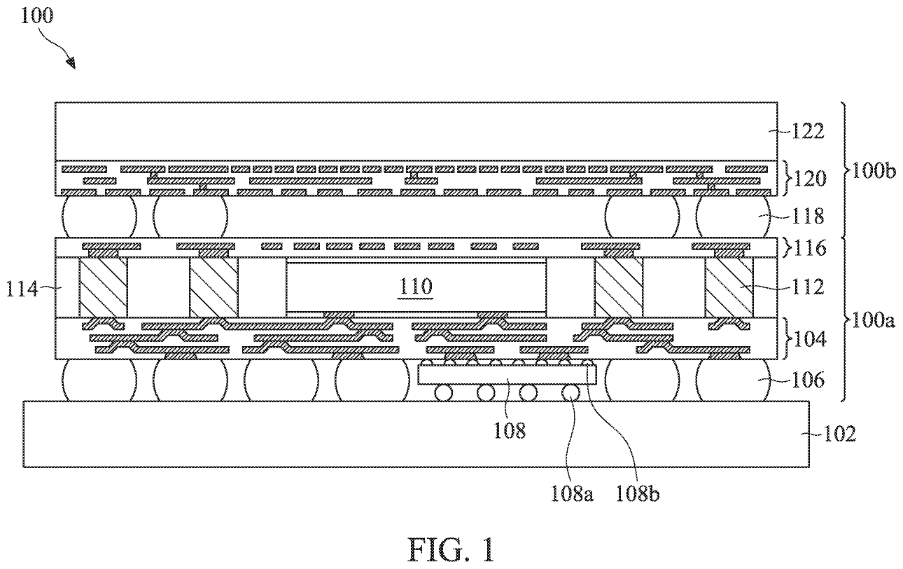

FIG. 1 is a cross-section view of a semiconductor package structure 100 in accordance with some embodiments of the present disclosure. Additional features can be added to the semiconductor package structure 100. Some of the features described below can be replaced or eliminated for different embodiments. To simplify the diagram, only a portion of the semiconductor package structure 100 is illustrated.

As shown in FIG. 1, the semiconductor package structure 100 includes a first package structure 100a and a second package structure 100b stacked vertically over a substrate 102, in accordance with some embodiments. The substrate 102 may be a coreless/core substrate or a printed circuit board (PCB). The substrate 102 may be formed of polypropylene (PP), Polyimide, BT/Epoxy, Prepreg, ABF, ceramic material or other suitable material. Any desired semiconductor element may be formed in and on the substrate 102. However, in order to simplify the figures, only the flat substrate 102 is illustrated.

The first package structure 100a may have a frontside and a backside opposite thereto. The first package structure 100a may have a first redistribution layer 104 on the frontside and a second redistribution layer 116 on the backside. The first redistribution layer 104 and the second redistribution layer 116 may each include one or more conductive layers and passivation layers, wherein the conductive layers may be disposed in the passivation layers. The conductive layers may include metal, such as copper, titanium, tungsten, aluminum, the like, or a combination thereof. The passivation layers may include a polymer layer, for example, polyimide (PI), polybenzoxazole (PBO), benzocyclobutene (BCB), epoxy, the like, or a combination thereof. Alternatively, the passivation layers may include a dielectric layer, such as silicon oxide, silicon nitride, silicon oxynitride, the like, or a combination thereof.

As shown in FIG. 1, the first redistribution layer 104 includes more conductive layers and passivation layers than the second redistribution layer 116, in accordance with some embodiments. The first redistribution layer 104 may be thicker than the second redistribution layer 116, but the present disclosure is not limit thereto. For example, the second redistribution layer 116 may be thicker than or substantially equal to the first redistribution layer 104.

As shown in FIG. 1, the first package structure 100a includes a plurality of conductive terminals 106 disposed below the first redistribution layer 104, in accordance with some embodiments. The conductive terminals 106 may electrically couple the first redistribution layer 104 to the substrate 102. The conductive terminals 106 may be formed of conductive materials, such as metal or alloy. For example, the conductive terminals 106 may be formed of solder, copper, aluminum, the like, or a combination thereof. In some embodiments, the conductive terminals 106 includes microbumps, controlled collapse chip connection (C4) bumps, solder balls, ball grid array (BGA) balls, the like, or a combination thereof.

As shown in FIG. 1, the first package structure 100a includes a silicon capacitor 108 disposed below the first redistribution layer 104 and electrically coupled to the first redistribution layer 104, in accordance with some embodiments. The silicon capacitor 108 may have a plurality of capacitor cells disposed in a semiconductor substrate, such as a silicon substrate. Since the silicon capacitor 108 has a greater thermal conductivity than a ceramic capacitor (such as a multi-layer ceramic capacitor (MLCC)), the efficiency of thermal dissipation can be increased. It should be noted that more than one silicon capacitors 108 may be disposed directly below a semiconductor die 110 (described below), and one silicon capacitor 108 is shown for illustrative purposes only.

The silicon capacitor 108 may be disposed adjacent to the conductive terminals 106. The silicon capacitor 108 may have a frontside and a backside opposite thereto. The frontside of the silicon capacitor 108 may face the first redistribution layer 104, and the backside of the silicon capacitor 108 may face the substrate 102.

As shown in FIG. 1, the first package structure 100a includes a first bump structure 108a disposed over the backside of the silicon capacitor 108, in accordance with some embodiments. The first bump structure 108a may electrically couple the silicon capacitor 108 to the substrate 102. In comparison to an underfill material which is generally used to connect an MLCC, the first bump structure 108a may have a greater thermal conductivity, so that the efficiency of thermal dissipation can be further increased. The first bump structure 108a may be formed of conductive materials, such as metal or alloy. In some embodiments, the first bump structure 108a includes solder balls, solder paste, or a combination thereof.

As shown in FIG. 1, the first package structure 100a includes a second bump structure 108b disposed over the frontside of the silicon capacitor 108, in accordance with some embodiments. The second bump structure 108b may electrically couple the silicon capacitor 108 to the first redistribution layer 104. The second bump structure 108b may be formed of conductive materials, such as metal or alloy. In some embodiments, the second bump structure 108b includes solder balls, solder paste, or a combination thereof. It should be noted that the numbers and configurations of the first bump structures 108a and the second bump structures 108b are shown for illustrative purposes only.

As shown in FIG. 1, the total thickness of the first bump structure 108a, the second bump structure 108b, and the silicon capacitor 108 may be substantially equal to the thickness of the conductive terminals 106. As a result, the first bump structure 108a may connect the substrate 102 and the silicon capacitor 108, and the second bump structure 108b may connect the first redistribution layer 104 and the silicon capacitor 108, and thus the heat from a semiconductor die 110 (described below) can be transferred to the substrate 102 through the first bump structure 108a, the second bump structure 108b, and the silicon capacitor 108.

As shown in FIG. 1, the first package structure 100a includes a semiconductor die 110 disposed over the first redistribution layer 104, in accordance with some embodiments. The semiconductor die 110 may be electrically coupled to the substrate 102 through the first redistribution layer 104, the conductive terminals 106, the first bump structure 108a, the second bump structure 108b, and the silicon capacitor 108.

According to some embodiments, the semiconductor die 110 includes a SoC die, a logic device, a memory device, a radio frequency (RF) device, the like, or any combination thereof. For example, the semiconductor die 110 may include a micro control unit (MCU) die, a microprocessor unit (MPU) die, a power management integrated circuit (PMIC) die, a global positioning system (GPS) device, an accelerated processing unit (APU) die, a central processing unit (CPU) die, a graphics processing unit (GPU) die, an input-output (10) die, a dynamic random access memory (DRAM) controller, a static random-access memory (SRAM), a high bandwidth memory (HBM), the like, or any combination thereof.

According to some embodiments, the first package structure 100a may include more than one semiconductor dies. In addition, the first package structure 100a may also include one or more passive components (not illustrated), such as resistors, capacitors, inductors, or a combination thereof.

As shown in FIG. 1, the first package structure 100a includes a plurality of conductive pillars 112 disposed over the first redistribution layer 104, in accordance with some embodiments. The conductive pillars 112 may electrically couple the second redistribution layer 116 to the first redistribution layer 104. The conductive pillars 112 may be formed of metal, such as copper, tungsten, the like, or a combination thereof.

As shown in FIG. 1, the first package structure 100a includes a molding material 114 disposed between the first redistribution layer 104 and the second redistribution layer 116, in accordance with some embodiments. The molding material 114 may include a nonconductive material, such as a moldable polymer, an epoxy, a resin, the like, or a combination thereof. As shown in FIG. 1, the sidewalls of the molding material 114 may be substantially coplanar with the sidewalls of the first redistribution layer 104 and the second redistribution layer 116.

The molding material 114 may surround the semiconductor die 110 and the conductive pillars 112, and may adjoin the sidewalls of the semiconductor die 110 and the conductive pillars 112. As shown in FIG. 1, the molding material 114 may fill in gaps between the conductive pillars 112, and between the semiconductor die 110 and the conductive pillars 112. The molding material 114 may protect the semiconductor die 110 and the conductive pillars 112 from the environment, thereby preventing these components from damage due to, for example, the stress, the chemicals and/or the moisture.

As shown in FIG. 1, the second package structure 100b is disposed over the first package structure 100a and is electrically coupled to the second redistribution layer 116 through a plurality of conductive terminals 118, in accordance with some embodiments. The conductive terminals 118 may be similar to the conductive terminals 106, and will not be repeated.

As shown in FIG. 1, the second package structure 100b includes a substrate 120, in accordance with some embodiments. The substrate 120 may have a wiring structure therein. In some embodiments, the wiring structure of the substrate 120 includes conductive layers, conductive vias, conductive pillars, the like, or a combination thereof. The wiring structure of the substrate 120 may be formed of metal, such as copper, titanium, tungsten, aluminum, the like, or a combination thereof.

The wiring structure of the substrate 120 may be disposed in inter-metal dielectric (IMD) layers. In some embodiments, the IMD layers may be formed of organic materials, such as a polymer base material, a non-organic material, such as silicon nitride, silicon oxide, silicon oxynitride, the like, or a combination thereof. Any desired semiconductor element may be formed in and on the substrate 120. However, in order to simplify the diagram, only the flat substrate 120 is illustrated.

As shown in FIG. 1, the second package structure 100b includes a molding material 122 disposed over the substrate 120 and one or more semiconductor components (not illustrated) surrounded by the molding material 122, in accordance with some embodiments. The molding material 122 may be similar to the molding material 114, and will not be repeated.

The semiconductor components may include one or more same or different devices. For example, the semiconductor components may include memory dies, such as a dynamic random access memory (DRAM). The second package structure 100b may also include one or more passive components (not illustrated), such as resistors, capacitors, inductors, or a combination thereof.

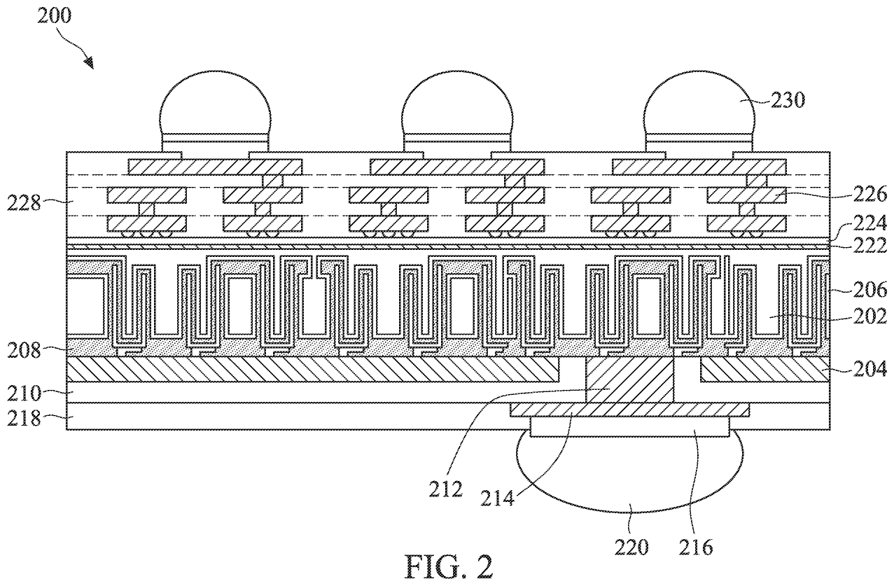

FIG. 2 is a cross-sectional view of a silicon capacitor 200 of a semiconductor package structure, in accordance with some embodiments of the present disclosure. The silicon capacitor 200 may include the same or similar components as that of the silicon capacitor 108, which is illustrated in FIG. 1, and for the sake of simplicity, those components will not be discussed in detail again.

As shown in FIG. 2, the silicon capacitor 200 includes a semiconductor substrate 202, in accordance with some embodiments. The semiconductor substrate 202 may be formed of any suitable semiconductor material, such as silicon, and may be doped (e.g., using p-type or n-type dopants) or undoped. The semiconductor substrate 202 may have a first surface and a second surface opposite thereto.

As shown in FIG. 2, the silicon capacitor 200 may have a plurality of capacitor cells embedded in the semiconductor substrate 202. The capacitor cells may extend from the first surface of the semiconductor substrate 202 toward the second surface of the semiconductor substrate 202. In particular, the top portion of the capacitor cells is disposed in the semiconductor substrate 202, and the bottom portion of the capacitor cells is disposed below the semiconductor substrate 202.

The capacitor cells may include electrodes 206, which include top electrodes and bottom electrodes, and an interlayer dielectric layer 208 between the top electrodes and the bottom electrodes. In some embodiments, the electrodes 206 are formed of conductive materials, such as metal, alloy, polysilicon, other suitable conductive material, or a combination thereof. The top electrodes and the bottom electrodes may be made of the same material or different materials. In some embodiments, the interlayer dielectric layer 208 is formed of a high-k dielectric material, such as aluminum oxide.

As shown in FIG. 2, the silicon capacitor 200 includes a conductive layer 204 disposed over the first surface of the semiconductor substrate 202, in accordance with some embodiments. The conductive layer 204 may electrically couple the capacitor cells to a ground. In particular, the capacitor cells may be electrically coupled to a ground on the first surface of the semiconductor substrate 202. In some embodiments, the conductive layer 204 is formed of conductive materials, such as metal, alloy, polysilicon, other suitable conductive material, or a combination thereof.

As shown in FIG. 2, the silicon capacitor 200 includes a dielectric layer 210 covering the sidewalls and a bottom surface of the conductive layer 204, in accordance with some embodiments. In some embodiments, the dielectric layer 210 is formed of a dielectric material, such as silicon oxide, silicon nitride, silicon oxynitride, the like, or a combination thereof.

As shown in FIG. 2, the silicon capacitor 200 includes a conductive via 212 disposed in the dielectric layer 210, in accordance with some embodiments. The conductive via 212 may extend through the dielectric layer 210 and may be electrically coupled to the capacitor cells. The conductive via 212 may connect the capacitor cells to the first bump structure 220 (described below), so that the silicon capacitor 200 can be bumped to the substrate 102 (as shown in FIG. 1). In some embodiments, the conductive via 212 is formed of conductive materials, such as metal, alloy, polysilicon, other suitable conductive material, or a combination thereof.

As shown in FIG. 2, the silicon capacitor 200 includes a conductive line 214 disposed below the conductive via 212, in accordance with some embodiments. In some embodiments, the conductive line 214 is formed of conductive materials, such as metal, alloy, polysilicon, other suitable conductive material, or a combination thereof.

As shown in FIG. 2, the silicon capacitor 200 includes a conductive pad 216 disposed below the conductive line 214, in accordance with some embodiments. In some embodiments, the conductive pad 216 is formed of conductive materials, such as metal or alloy. For example, the conductive pad 216 may be formed of nickel, tin, copper, tungsten, the like, or a combination thereof. The conductive layer 204, the conductive via 212, the conductive line 214, and the conductive pad 216 may be made of the same material or different materials.

As shown in FIG. 2, the silicon capacitor 200 includes a solder resist layer 218 covering the sidewalls and a bottom surface of the conductive line 214 and covering the sidewalls of the conductive pad 216, in accordance with some embodiments. The sidewalls of the conductive pad 216 may be partially covered by the solder resist layer 218 as shown in FIG. 2. Alternatively, the entire sidewalls of the conductive pad 216 may be covered by the solder resist layer 218. In some embodiments, the solder resist layer 218 is formed of a dielectric material, such as silicon oxide, silicon nitride, silicon oxynitride, the like, or a combination thereof.

As shown in FIG. 2, the silicon capacitor 200 includes a first bump structure 220 disposed below the conductive pad 216, in accordance with some embodiments. The first bump structure 220 may be electrically coupled to the capacitor cells through the conductive pad 216, the conductive line 214, and the conductive via 212. The sidewalls of the conductive pad 216 may be partially covered by the first bump structure 220 as shown in FIG. 2. The first bump structure 220 may be similar to the first bump structure 108a as shown in FIG. 1, and will not be repeated.

As shown in FIG. 2, the silicon capacitor 200 includes a conductive line 222 disposed over the second surface of the semiconductor substrate 202 and electrically coupled to the capacitor cells, in accordance with some embodiments. In some embodiments, the conductive line 222 is formed of conductive materials, such as metal, alloy, polysilicon, other suitable conductive material, or a combination thereof.

As shown in FIG. 2, the silicon capacitor 200 includes a dielectric layer 224 disposed over the conductive line 222, in accordance with some embodiments. In some embodiments, the dielectric layer 224 is formed of a dielectric material, such as silicon oxide, silicon nitride, silicon oxynitride, the like, or a combination thereof.

As shown in FIG. 2, the silicon capacitor 200 includes a wiring structure 226 disposed over the dielectric layer 224, in accordance with some embodiments. The wiring structure 226 may be electrically coupled to the capacitor cells. In some embodiments, the wiring structure 226 includes conductive layers, conductive vias, conductive pillars, the like, or a combination thereof. The wiring structure 226 may be formed of metal, such as copper, titanium, tungsten, aluminum, the like, or a combination thereof.

As shown in FIG. 2, the wiring structure 226 may be disposed in inter-metal dielectric (IMD) layers 228. In some embodiments, the IMD layers 228 may be formed of organic materials, such as a polymer base material, a non-organic material, such as silicon nitride, silicon oxide, silicon oxynitride, the like, or a combination thereof.

As shown in FIG. 2, the silicon capacitor 200 includes a second bump structure 230 disposed over the wiring structure 226 and electrically coupled to the capacitor cells through the wiring structure 226 and the conductive line 222, in accordance with some embodiments. The second bump structure 230 may be similar to the second bump structure 108b as shown in FIG. 1, and will not be repeated.

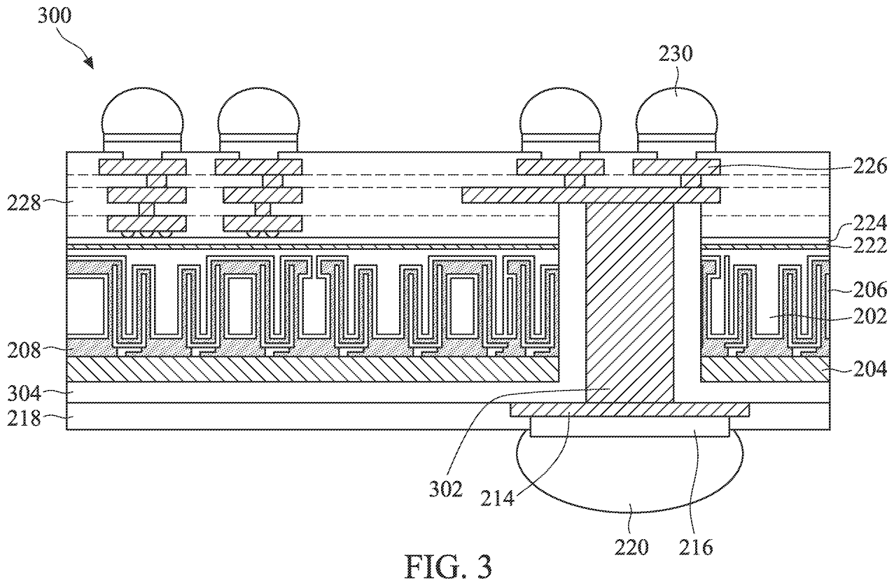

FIG. 3 is a cross-section view of a silicon capacitor 300 of a semiconductor package structure, in accordance with some embodiments of the present disclosure. It should be noted that the silicon capacitor 300 may include the same or similar components as that of the silicon capacitor 200, which is illustrated in FIG. 2, and for the sake of simplicity, those components will not be discussed in detail again. In comparison with the embodiment of FIG. 2 where the conductive via 212 is disposed below the semiconductor substrate 202, in the following embodiments, a conductive via passes through the semiconductor substrate 202.

As shown in FIG. 3, the silicon capacitor 300 includes a conductive via 302 extending through the semiconductor substrate 202, in accordance with some embodiments. The conductive via 302 may be electrically coupled to the wiring structure 226 and may electrically couple the first bump structure 220 to the second bump structure 230. In some embodiments, the conductive via 302 is formed of conductive materials, such as metal, alloy, polysilicon, other suitable conductive material, or a combination thereof.

As shown in FIG. 3, one of the first bump structures 220 and two of the second bump structures 230 may be disposed on opposite sides of the conductive via 302. However, the numbers and configurations of the first bump structures 220 and the second bump structures 230 are shown for illustrative purposes only.

As shown in FIG. 3, the silicon capacitor 300 includes a dielectric layer 304 extending through the semiconductor substrate 202 and covering the sidewalls of the conductive via 302, in accordance with some embodiments. The dielectric layer 304 may be similar to the dielectric layer 210 as shown in FIG. 2, and will not be repeated. The dielectric layer 304 and the IMD layers 228 may be made of the same material or different materials.

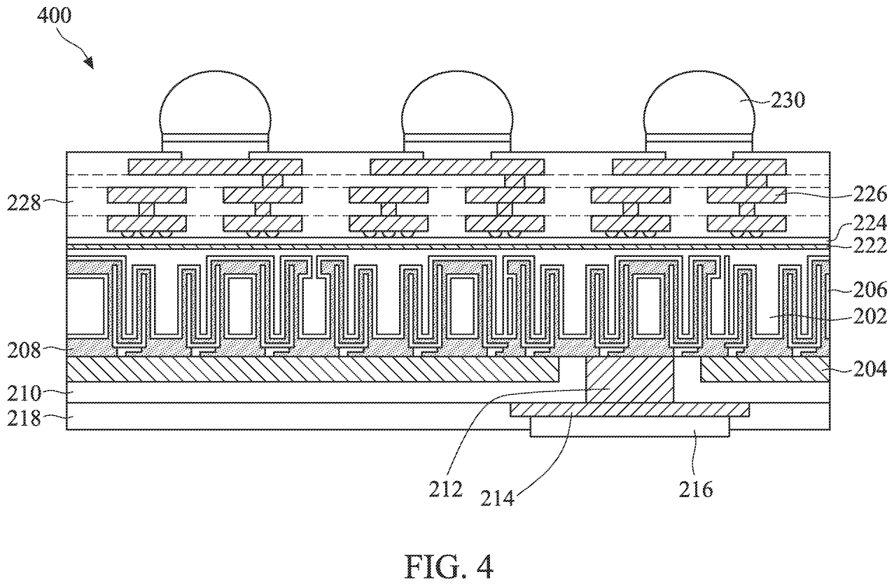

FIG. 4 is a cross-section view of a silicon capacitor 400 of a semiconductor package structure, in accordance with some embodiments of the present disclosure. It should be noted that the silicon capacitor 400 may include the same or similar components as that of the silicon capacitor 200, which is illustrated in FIG. 2, and for the sake of simplicity, those components will not be discussed in detail again. In comparison with the embodiment of FIG. 2 where the first bump structure 220 is one of the components of the silicon capacitor 200, in the following embodiments, the first bump structure is formed over the substrate 102 (shown in FIG. 1) and is not illustrated in FIG. 4.

As shown in FIG. 4, the bottom surface of the conductive pad 216 is exposed by the solder resist layer 218, in accordance with some embodiments. The first bump structure may be formed over the substrate 102 (shown in FIG. 1), and the conductive pad 216 may connect the first bump structure (such as the first bump structure 108a in FIG. 1) when the silicon capacitor 400 is disposed over the substrate 102. As a result, the heat from the semiconductor die 110 (shown in FIG. 1) can be transferred to the substrate 102 through the silicon capacitor 400 and the first bump structure.

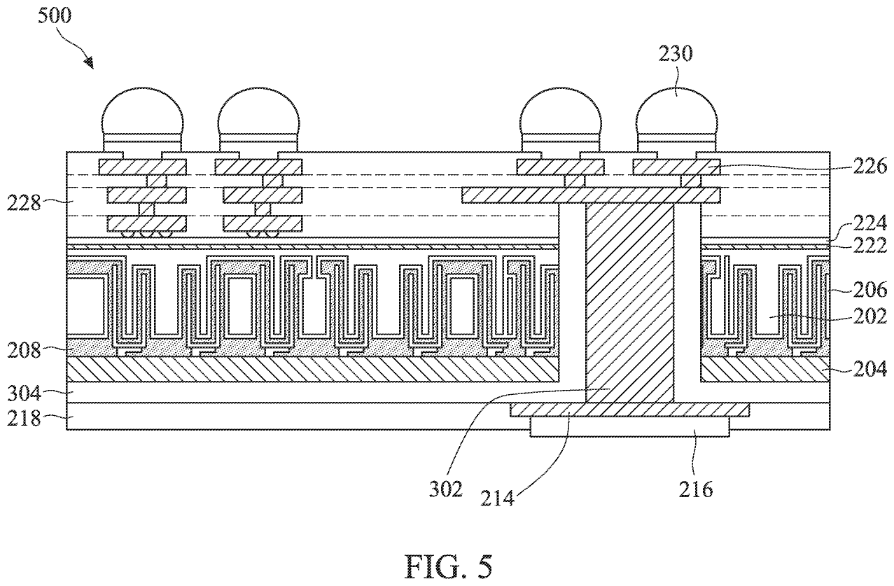

FIG. 5 is a cross-section view of a silicon capacitor 500 of a semiconductor package structure, in accordance with some embodiments of the present disclosure. It should be noted that the silicon capacitor 500 may include the same or similar components as that of the silicon capacitor 300, which is illustrated in FIG. 3, and for the sake of simplicity, those components will not be discussed in detail again. In comparison with the embodiment of FIG. 3 where the first bump structure 220 is one of the components of the silicon capacitor 300, in the following embodiments, the first bump structure is formed over the substrate 102 (shown in FIG. 1) and is not illustrated in FIG. 5.

As shown in FIG. 5, the bottom surface of the conductive pad 216 is exposed by the solder resist layer 218, in accordance with some embodiments. The first bump structure may be formed over the substrate 102 (shown in FIG. 1), and the conductive pad 216 may connect the first bump structure (such as the first bump structure 108a in FIG. 1) when the silicon capacitor 500 is disposed over the substrate 102. As a result, the heat from a semiconductor die 110 (shown in FIG. 1) can be transferred to the substrate 102 through the silicon capacitor 500 and the first bump structure.

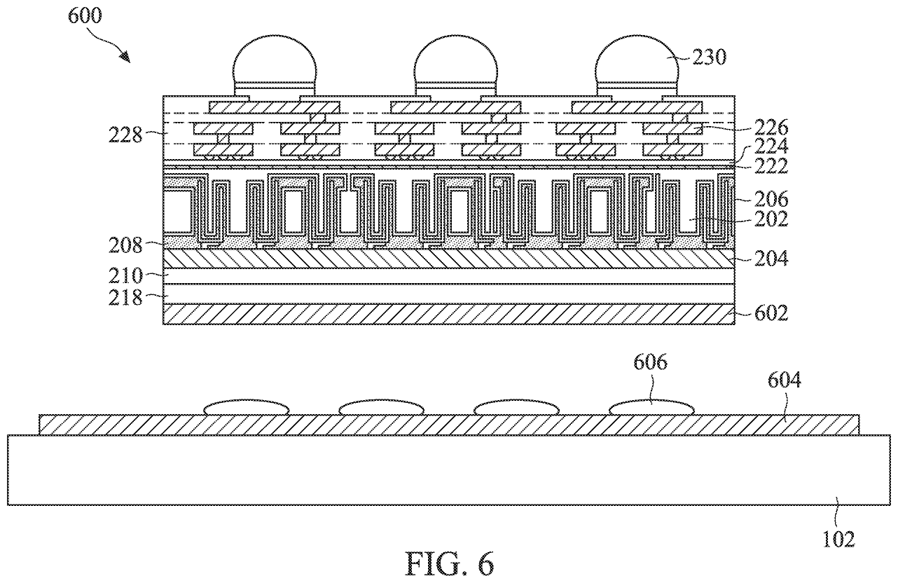

FIG. 6 is a cross-section view of a silicon capacitor 600 of a semiconductor package structure, in accordance with some embodiments of the present disclosure. It should be noted that the silicon capacitor 600 may include the same or similar components as that of the silicon capacitor 200, which is illustrated in FIG. 2, and for the sake of simplicity, those components will not be discussed in detail again. In comparison with the embodiment of FIG. 2 where the conductive via 212, the conductive line 214, and the conductive pad 216 are adopted to connect the first bump structure 220, in the following embodiments, a conductive layer 602 is adopted to connect a first bump structure 606.

As shown in FIG. 6, the silicon capacitor 600 includes a conductive layer 602 disposed below the solder resist layer 218 and electrically coupled to the capacitor cells, in accordance with some embodiments. In particular, the bottom portion of the silicon capacitor 600 may include the conductive layer 602. In some embodiments, the conductive layer 602 is formed of conductive materials, such as metal or alloy. For example, the conductive layer 602 may be formed of nickel, tin, the like, or a combination thereof. The conductive layer 602 may be formed by plating, such as electroplating, electroless plating, or the like.

As shown in FIG. 6, the silicon capacitor 600 includes a ground pad 604 disposed over the substrate 102 and electrically coupled to a ground, in accordance with some embodiments. The ground pad 604 may cover a portion of the top surface of the substrate. In some embodiments, the ground pad 604 is formed of conductive materials, such as metal or alloy. For example, the conductive layer 602 may be formed of nickel, tin, the like, or a combination thereof.

As shown in FIG. 6, the silicon capacitor 600 includes a first bump structure 606 disposed over the ground pad 604 and electrically coupled to the ground pad 604, in accordance with some embodiments. When the silicon capacitor 600 is disposed over the first bump structure 606, the capacitor cells may be electrically coupled to the substrate 102 through the conductive layer 602 and the first bump structure 606. The first bump structure 606 may be formed of conductive materials, such as metal or alloy. In some embodiments, the first bump structure 606 includes solder balls, solder paste, or a combination thereof.

In summary, a semiconductor package structure has a silicon capacitor as a decoupling capacitor, in accordance with some embodiments. The silicon capacitor may be disposed between a semiconductor die and a substrate. Since the silicon capacitor has a better thermal conductivity than a ceramic capacitor, the heat from the semiconductor die can be transferred to the substrate through the silicon capacitor. As a result, the efficiency of thermal dissipation can be improved.

In addition, a bump structure is used to connect the silicon capacitor and the substrate, in accordance with some embodiments. Since the bump structure has a better thermal conductivity than an underfill material, the heat from the semiconductor die can be transferred to the substrate through the silicon capacitor and the bump structure. Therefore, the efficiency of thermal dissipation can be further increased.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a substrate;
a first redistribution layer disposed over the substrate;
a semiconductor die disposed over the first redistribution layer;
a silicon capacitor disposed below the first redistribution layer and electrically coupled to the semiconductor die, wherein the silicon capacitor comprises:
a semiconductor substrate; and
a plurality of capacitor cells embedded in the semiconductor substrate; and a first bump structure disposed between the silicon capacitor and the substrate.

2. The semiconductor package structure as claimed in claim 1, wherein the silicon capacitor further comprises a second bump structure electrically coupling the plurality of capacitor cells to the first redistribution layer.

3. The semiconductor package structure as claimed in claim 2, wherein the silicon capacitor further comprises a wiring structure electrically coupling the plurality of capacitor cells to the second bump structure.

4. The semiconductor package structure as claimed in claim 3, further comprising a conductive via extending through the semiconductor substrate and electrically coupling the wiring structure to the first bump structure.

5. The semiconductor package structure as claimed in claim 1, further comprising a conductive via disposed below the semiconductor substrate and electrically coupling the plurality of capacitor cells to the first bump structure.

6. The semiconductor package structure as claimed in claim 1, wherein a bottom portion of the silicon capacitor comprises a conductive layer electrically coupled to the plurality of capacitor cells.

7. The semiconductor package structure as claimed in claim 1, wherein a top portion of the plurality of capacitor cells is disposed in the semiconductor substrate, and a bottom portion of the plurality of capacitor cells is disposed below the semiconductor substrate.

8. The semiconductor package structure as claimed in claim 7, wherein the bottom portion of the plurality of capacitor cells is electrically coupled to a ground.

9. The semiconductor package structure as claimed in claim 1, further comprising a ground pad disposed between the first bump structure and the substrate.

10. The semiconductor package structure as claimed in claim 1, further comprising:
a second redistribution layer disposed over the semiconductor die; and
a molding material disposed between the first redistribution layer and the second redistribution layer and surrounding the semiconductor die.

11. A semiconductor package structure, comprising:
a first redistribution layer;
a semiconductor die disposed over the first redistribution layer; and
a silicon capacitor disposed below the first redistribution layer and electrically coupled to the semiconductor die through the first redistribution layer, wherein the silicon capacitor comprises:
a semiconductor substrate having a first surface and a second surface opposite thereto;
a plurality of capacitor cells extending from the first surface of the semiconductor substrate toward the second surface of the semiconductor substrate;
a first bump structure disposed over the first surface of the semiconductor substrate and electrically coupled to the plurality of capacitor cells; and
a second bump structure disposed over the second surface of the semiconductor substrate and electrically coupled to the first redistribution layer.

12. The semiconductor package structure as claimed in claim 11, wherein the silicon capacitor further comprises a wiring structure disposed between the second bump structure and the semiconductor substrate.

13. The semiconductor package structure as claimed in claim 11, wherein the silicon capacitor further comprises a conductive via extending between the first bump structure to the second bump structure and electrically coupling the first bump structure to the second bump structure.

14. The semiconductor package structure as claimed in claim 11, wherein the silicon capacitor further comprises a conductive via disposed between the semiconductor substrate and the first bump structure.

15. The semiconductor package structure as claimed in claim 11, wherein the plurality of capacitor cells are electrically coupled to a ground on the first surface of the semiconductor substrate.

16. The semiconductor package structure as claimed in claim 11, further comprising:
a substrate disposed below the silicon capacitor, wherein the silicon capacitor is electrically coupled to the substrate through the first bump structure; and
a plurality of conductive terminals adjacent to the silicon capacitor and electrically coupling the first redistribution layer to the substrate.

17. A semiconductor package structure, comprising:
a first package structure comprising:
a first redistribution layer;
a semiconductor die disposed over the first redistribution layer;
a second redistribution layer disposed over the semiconductor die;
a silicon capacitor disposed below the first redistribution layer and electrically coupled to the semiconductor die; and
a bump structure disposed below the silicon capacitor.

18. The semiconductor package structure as claimed in claim 17, wherein the first package structure further comprises:
a conductive pillar disposed between the first redistribution layer and the second redistribution layer and adjacent to the semiconductor die; and
a molding material surrounding the semiconductor die and the conductive pillar.

19. The semiconductor package structure as claimed in claim 17, further comprising a second package structure disposed over the second redistribution layer.

20. The semiconductor package structure as claimed in claim 17, further comprising a substrate disposed below the first package structure and in contact with the bump structure.
